(19) United States
(12) Patent Application Publication
(10) Pub. No.: US 2015/0096893 A1
(43) Pub. Date: Apr. 9, 2015

(54) ALUMINUM ALLOY FOR DIE-CASTING, METAL CASE FOR PORTABLE ELECTRICAL DEVICE AND METHOD OF MANUFACTURING THE METAL CASE

(71) Applicant: GK Corporation, Ltd., Ansan-si (KR)

(72) Inventors: Jong Hoon JEONG, Siheung-si (KR); Dong Sung SHIN, Siheung-si (KR)

(21) Appl. No.: 14/495,288

(22) Filed: Sep. 24, 2014

(30) Foreign Application Priority Data
Oct. 7, 2013 (KR) 10-2013-0119389

(51) Int. Cl. H05K 5/04; B22D 17/20; C25D 11/24; C22C 21/00

(52) U.S. Cl. CPC H05K 5/04; C22C 21/00; B22D 17/2015; C25D 11/246; C25D 11/243
USPC 205/50; 420/540; 205/202

(57) ABSTRACT

An aluminum alloy for die-casting, a metal case for a portable electrical device, and a method of manufacturing the metal case are disclosed. The aluminum alloy for die-casting includes about 1.95% to about 4.10% by weight of manganese, about 0.1% to about 2.0% by weight of zinc, about 0.3% to about 0.8% by weight of zircon, about 0.03% to about 0.09% by weight of titanium, and a remainder of aluminum. Thus, the aluminum alloy may provide a mechanical property and a glossiness that are appropriate for a case of a portable electrical device.

### CROSS REFERENCE TO RELATED APPLICATION

This application claims priority from and the benefit of Korean Patent Application No. 10-2013-0119389, filed on Oct. 7, 2013, which is hereby incorporated by reference for all purposes as if fully set forth herein.

### BACKGROUND

1. Field

Example embodiments relate to an aluminum alloy for die-casting, a metal case for a portable electrical device, and a method of manufacturing the metal case. More particularly, example embodiments relate to an aluminum alloy for die-casting, which can achieve uniform coloring and high glossiness through a following color-anodizing process to improve fanciness of a portable electrical device, a metal case for a portable electrical device, and a method of manufacturing the metal case.

2. Discussion of the Background

Recently, competition between product makers for reducing size and thickness of a product is intense as portability and high-functionality is required in the field of a portable electrical device such as a mobile phone, a digital camera, a multimedia player, or the like. Furthermore, importance of an external design of a product is being increased for selection of a consumer as a fashion becomes an important factor for consumption.

Thus, a plastic material, for example, polymer, that can allow various colors and complicated designs is being used for an external body of an electrical device.

However, a plastic body has a low surface hardness. Thus, a surface defect such as a scratch may be easily generated. Furthermore, when the plastic body is exposed to an external light from the sun, a color thereof may be changed. Furthermore, the plastic body is may be easily damaged by impact. Furthermore, reducing a thickness of the plastic body is limited so that the plastic body may have a desired structural strength.

Thus, researches and developments are being conducted for using a metal such as magnesium, titanium or aluminum alloy, which has a high structural strength and a high surface hardness to have a high resistance against scratch and to be capable of forming a product having a small thickness and a small size, as a material for a case of an electrical device.

However, coloring a metal is difficult and limited so that a product from a metal hardly achieves various colors.

A rolled/extruded aluminum material can achieve various colors. Thus, the rolled/extruded aluminum material is being widely used for a construction structure exterior, a food container such as a can or the like.

As the above, the rolled/extruded aluminum material can achieve various colors. However, making a complicated shape such as rib, boss or the like, which is required for an electrical device, is difficult.

Thus, a case of an electrical device, which has a complicated shape, is manufactured through a die-casting process. In the die-casting process, a molten metal is injected into a mold having a complicated inner structure corresponding to a shape of a desired product. Thus, a molten metal needs to have a proper liquidity.

ADC12, which is well-known aluminum alloy for die-casting, has a high amount of silicon to have a proper liquidity.

However, an electrochemical reaction of the aluminum alloy having a high amount of silicon hardly is difficult because of segregation and precipitation. Thus, a die-casted product from the aluminum alloy may have smear, and may have a low gloss. Thus, processing a following anodizing process may be difficult, or uniform coloring may be difficult due to surface reduction.

For solving the problem, methods for performing anodizing after depositing aluminum on a die-casted product are disclosed in Korean Patent No. 10-1016278, and Korean Patent Publications No. 10-2005-0102018, No. 10-2011-0137107, No. 10-2012-0045469, No. 10-2012-0116557, and No. 10-2013-0040322.

For other methods, US Patent Publication No. 2011-0195271 discloses a method of disposing a zinc alloy veneer plate in a die before injecting aluminum alloy and anodizing the veneer plate of a die-casted product.

Furthermore, methods for anodizing aluminum alloy having a reduced amount of silicon are disclosed in Korean Patent No. 10-1055373, and Korean Patent Publications No. 10-2010-0014505, No. 10-2011-0111486, No. 10-2011-0138063, No. 10-2012-0084640, No. 10-2011-0038357 and No. 10-2012-0048174.

### SUMMARY

Example embodiments provide aluminum alloy capable of providing liquidity appropriate for die-casting, and providing strength, gloss and color appropriate for an external case of an electrical device without including silicon. Exterior of a portable electrical device needs to satisfy various conditions, which includes durability and appearance to have commercial viability. The aluminum alloy may provide a portable electrical device having a light weight and a superior appearance useful for intriguing consumers.

The present invention relates to an aluminum alloy for a case of a portable electrical apparatus, a case including the aluminum alloy, and a method for manufacturing the case. The aluminum alloy may be used for a case of a portable electrical apparatus. The case may have a superior appearance, durability and portability by combination of the aluminum alloy, the die-casting process and finishing processes. Al—Mn—Zn—Zr alloy according to an exemplary embodiment of the present invention have a high reflectivity and a high glossiness, and may provide a portable die-casted product that has no visible defect in a condition of an anodizing process.

The aluminum alloy may provide a mechanical property, a die-castability and an anodizability that are appropriate for a desired product. A die-casting process may provide a portable die-casted product that has no visible defect. Finishing processes provide a durability, a UN resistance and an abrasion resistance to a die-casted product having a fanciness.

An aluminum alloy for die-casting according to an exemplary embodiment of the present invention includes about 1.95% to about 4.10% by weight of manganese, about 0.1% to about 2.0% by weight of zinc, about 0.3% to about 0.8% by weight of zircon, about 0.03% to about 0.09% by weight of titanium, and a remainder of aluminum.

In an embodiment, the aluminum alloy may preferably include about 2.5% to about 3.5% by weight of manganese.

In an embodiment, the aluminum alloy further includes comprising about 0.01% to about 0.09% by weight of strontium to inhibit crystallization of an acicular structure or a lamella structure by impurities and to refine the aluminum alloy.

In an embodiment, an amount of aluminum is preferably equal to or more than about 94% by weight to prevent seizure and to maintain liquidity.

A method for manufacturing a case of a portable electrical apparatus according to an exemplary embodiment of the present invention includes forming a molten aluminum alloy including about 1.95% to about 4.10% by weight of manganese, about 0.1% to about 2.0% by weight of zinc, about 0.3% to about 0.8% by weight of zircon, about 0.03% to about 0.09% by weight of titanium, about 0.01% to about 0.09% by weight of strontium, and a remainder of aluminum, providing the molten aluminum alloy into a die, separating an aluminum alloy die-casted product from the die, anodizing a surface of the aluminum alloy die-casted product, providing a dye into fine pores at a surface of the anodized aluminum alloy die-casted product and sealing the fine pores.

In an embodiment, a temperature of the molten aluminum alloy is about 700° C. to about 800° C., and preferably about 760° C. to about 790° C. A temperature of the die is about 200° C. to about 250° C. to prevent deterioration by over-cooling.

A case of a portable electrical apparatus according to an exemplary embodiment of the present invention include a core layer including aluminum alloy including about 1.95% to about 4.10% by weight of manganese, about 0.1% to about 2.0% by weight of zinc, about 0.3% to about 0.8% by weight of zircon, about 0.03% to about 0.09% by weight of titanium, about 0.01% to about 0.09% by weight of strontium, and a remainder of aluminum, an anodized layer including a plurality of fine pores formed at a surface of the core layer and having a depth, a dye layer disposed in and combined with the fine pores; and a sealing layer covering entrances of the fine pores.

In an embodiment, a glossiness of the case is preferably about 150% to 300% of glossiness with 60 degrees of an incident angle, when 100% of glossiness may be defined as 10% of reflectivity with 60 degrees of an incident angle.

In an embodiment, a tensile strength of the case is about 180 MPa to about 230 MPa.

According to the aluminum alloy for die-casting according to an exemplary embodiment of the present invention, a die-casted metal case that has a superior die-castability, no or few surface defects and a high strength and a high elongation, which are required for a case of a portable electrical apparatus, may be obtained. Furthermore, a die-casted metal case that has a high hardness and a high glossiness may be obtained through anodizing. Furthermore, since the die-casted metal case has no or few surface defects, uniform and various coloring are possible. Thus, the die-casted metal case may have superior and luxurious appearance.

### BRIEF DESCRIPTION OF THE DRAWINGS

The above and other features and advantages of the present inventive concept will become more apparent by describing in detailed example embodiments thereof with reference to the accompanying drawings, in which:

FIG. 1 is a binary phase equilibrium diagram of aluminum-manganese.

FIG. 2 is a ternary phase equilibrium diagram of aluminum-manganese of aluminum-manganese-zinc.

FIG. 3 is a graph showing a hardness with respect to an amount of a metal solute dissolved in aluminum.

FIG. 4 is an optical microscopic picture, which shows a surface of the die-casted product of Example 1.

FIG. 5 is an optical microscopic picture, which shows a surface of the die-casted product of Example 2.

FIG. 6 is an optical microscopic picture, which shows a surface of the die-casted product of Comparative Example 1.

FIG. 7 is a scanning electron microscopic (SEM) picture, which shows a surface of the die-casted product of Example 1.

FIG. 8 is an SEM picture, which shows a surface of the die-casted product of Example 2.

FIG. 9 is an SEM picture, which shows a surface of the die-casted product of Comparative Example 1.

FIG. 10 is an optical microscopic picture, which shows a surface of the die-casted product of Example 1 after anodizing the die-casted product.

FIG. 11 is an optical microscopic picture, which shows a surface of the die-casted product of Example 2 after anodizing the die-casted product.

FIG. 12 is an optical microscopic picture, which shows a surface of the die-casted product of Comparative Example 1 after anodizing the die-casted product.

FIG. 13 is a cross-sectional view illustrating a case 100 of a portable electrical case manufacture by using aluminum alloy according to an exemplary embodiment of the present invention.

FIG. 14 is a picture showing the sample cases manufactured by using the aluminum alloy of Example 1.

FIG. 15 is a picture showing the sample cases manufactured by using the aluminum alloy of Example 2.

FIG. 16 is a picture showing the sample cases manufactured by using the aluminum alloy of Comparative Example 1.

### DETAILED DESCRIPTION OF THE ILLUSTRATED EMBODIMENTS

The present inventive concept now will be described more fully hereinafter with reference to the accompanying drawings, in which exemplary embodiments of the present invention are shown. The present inventive concept may, however, be embodied in many different forms and should not be construed as limited to the exemplary embodiments set fourth herein.

Rather, these exemplary embodiments are provided so that this disclosure will be thorough and complete, and will fully convey the scope of the present invention to those skilled in the art.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the present invention and does not pose a limitation on the scope of the present invention unless otherwise claimed. No language in the specification should be construed as indicating any non-claimed element as essential to the practice of the inventive concept as used herein.

Aluminum Alloy for Die-Casting

Aluminum alloy for die-casting according to an exemplary embodiment of the present invention includes about 1.95% to about 4.10% by weight of manganese (Mn), about 0.1% to about 2.0% by weight of zinc (Zn), about 0.3% to about 0.8% by weight of zircon (Zr), about 0.03% to about 0.09% by weight of titanium (Ti), about 0.01% to about 0.09% by weight of strontium (Sr), and a remainder of aluminum. The aluminum alloy may further include impurities such as iron, silicon or the like. An amount of the impurities may be small so that characteristics of the aluminum alloy are not affected thereby. It is preferred that an amount of the impurities is minimized.

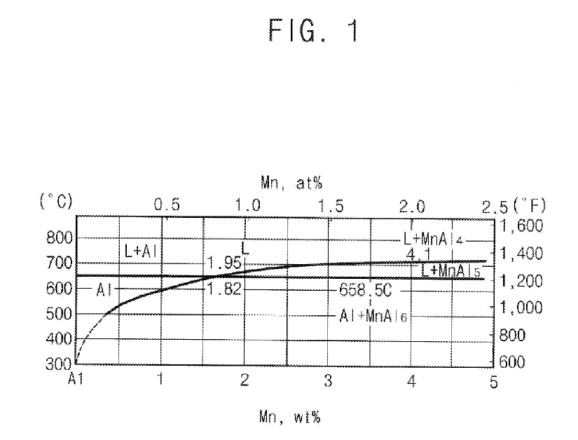

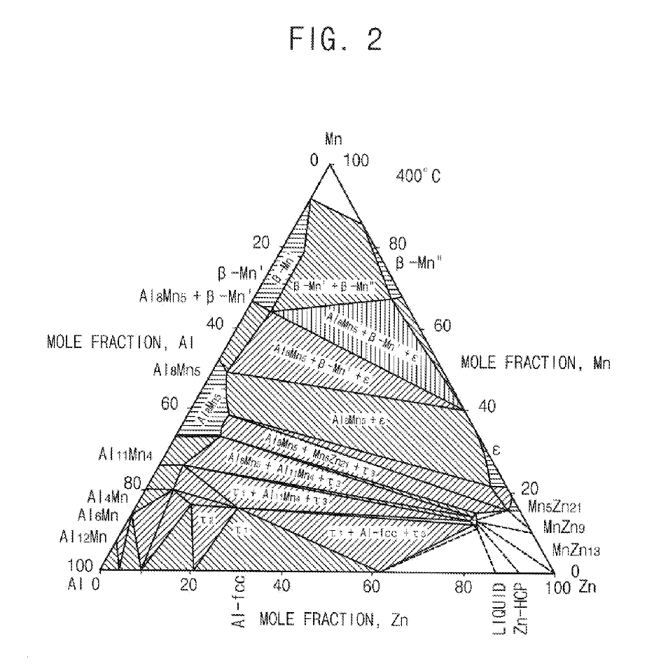

FIG. 1 is a binary phase equilibrium diagram of aluminum-manganese. FIG. 2 is a ternary phase equilibrium diagram of aluminum-manganese of aluminum-manganese-zinc. FIG. 3 is a graph showing a hardness with respect to an amount of a metal solute dissolved in aluminum.

The aluminum alloy for die-casting according to an exemplary embodiment of the present invention includes about 1.95% to about 4.10% by weight of manganese. Preferably, the aluminum alloy may include about 2.50% to about 3.5% by weight of manganese.

Manganese increases a recrystallization temperature of aluminum and promotes fibrous structure to inhibit growth of crystal grain. Furthermore, manganese is solid-solved in crystal lattice of aluminum to form a substitutional solid solution and to increase a mechanical strength of the aluminum alloy.

A eutectic composition of manganese to aluminum is about 1.95% by weight (a solubility is about 1.82% by weight) as shown in FIG. 1. Thus, when more manganese than about 1.95% by weight is solved to form super-saturation state and is cooled, remaining manganese, which does not form solid solution, is precipitated as an intermetallic compound of Al₆Mn in the course of solidification so that mechanical characteristics of the aluminum alloy are improved by solid solution strengthening and dispersion of fine precipitates. Al₆Mn that has dispersed second phase is electrochemically stable in aluminum and has a high corrosion resistance. Thus, Al₆Mn may improve strength and formability of the aluminum alloy.

When an amount of manganese is more than about 4.1% by weight, Al₁₂Mn rather than Al₆Mn may be precipitated. A rough intermetallic compound such as Al₁₂Mn may deteriorate surface characteristics of the aluminum alloy. Thus, an amount of manganese in the aluminum alloy may be about 1.95% to about 4.10% by weight, and preferably about 2.5% to about 3.5% by weight.

As illustrated in FIG. 3, larger amount of manganese may increase a hardness of the aluminum alloy by about 3.5% by weight.

When an amount of manganese is more than about 3.5% by weight, an intermetallic compound as a primary crystal may be formed thereby reducing glitter and causing color stain.

According to the exemplary embodiment of the present invention, the aluminum alloy may include about 2.5% to about 3.5% by weight of manganese. Thus, the aluminum alloy may provide a mechanical strength required for a case of a portable electrical device. An intermetallic compound formed as a primary crystal may be further prevented by combination with the following elements.

The aluminum alloy for die-casting according to an exemplary embodiment of the present invention includes about 0.1% to about 2.0% by weight of zinc. Zinc may increase reflectivity of an anodized and colored product so that gloss of the product may be entirely increased.

When an amount of zinc is less than about 0.1% by weight, gloss of the product is not substantially increased. Furthermore, when an amount of zinc is more than about 2.0% by weight, segregation may be caused so that it is difficult to achieve uniform appearance.

Even if zinc hardly increases a hardness of the aluminum alloy as illustrated in FIG. 3, zinc may improve grain refining or gloss.

The aluminum alloy for die-casting according to an exemplary embodiment of the present invention includes about 0.3% to about 0.8% by weight of zircon (Zr), and preferably includes about 0.4% to about 0.5% by weight of zircon.

Zircon refines a crystal grain of the aluminum alloy and forms Al₃Zr particles thereby reducing dislocation loop. Thus, non-uniform precipitation of S′ phase may be inhibited. Furthermore, zircon increases a mechanical strength of the aluminum alloy. When an amount of zircon is less than about 0.3% by weight, it is difficult to achieve a desired tensile strength. When an amount of zircon is more than about 0.8% by weight, an economic feasibility is reduced.

The aluminum alloy for die-casting according to an exemplary embodiment of the present invention includes about 0.03% to about 0.09% by weight of titanium, and preferably includes 0.05% to about 0.07% by weight of titanium.

Titanium refines a crystal grain of the aluminum alloy to promote generation of crystal nucleus in the course of solidification. Thus, when titanium is added to an aluminum alloy, a solidus line is lowered, and a range is reduced. Thus, castability is improved. Thus, a size of a large intermetallic compound of Al—Mn impurities is reduced, and the number thereof is increased. Furthermore, since a crystal grain is refined, a color after an anodizing process may be uniform, and a hardness of a product may be increased.

When an amount of titanium is less than about 0.03% by weight, an effect of refinement is little. When an amount of titanium is more than about 0.09% by weight, additional refinement is not achieved, and a liquidus line is increased, solubility and castability of the aluminum alloy may be deteriorated.

The aluminum alloy for die-casting according to an exemplary embodiment of the present invention includes out 0.01% to about 0.09% by weight of strontium, and preferably includes 0.05% to about 0.08% by weight of strontium.

Strontium changes an acicular structure or a lamella structure to a fibrous structure that is finely dispersed to inhibit crystallization of an intermetallic compound having an acicular structure or a lamella structure due to impurities such as iron or silicon and to refine a crystal grain of the aluminum alloy. Thus, deterioration due to impurities may be prevented. When an amount of strontium is less than about 0.01% by weight, segregation may not be prevented. When an amount of strontium is more than about 0.09% by weight, uniform distribution may not be improved.

Manufacturing Aluminum Alloy Ingot for Die-Casting

According to an exemplary embodiment of the present invention, an alloy-solving furnace includes three electric furnaces. The electric furnaces are rotationally moved to a molten-metal providing position, a degassing and stirring position and a stabilizing and ingot-tapping position by a turn table. Each of the electric furnaces may have a small capacity, for example, a capacity of 650 kg. The electric furnaces may be heated at an average temperature more than about 750° C. (at most 800° C.) by, for example, KANTHAL AF strip heater before alloy additives are added. Alloy additives are added in 99.9% molten metal of aluminum to form molten metal of aluminum alloy having a predetermined alloy composition.

For example, about 500 kg of molten metal of aluminum is provided at the molten-metal providing position. Alloy additives including about 1.95% to about 4.10% by weight of manganese, about 0.1% to about 2.0% by weight of zinc, about 0.3% to about 0.8% by weight of zircon, about 0.03% to about 0.09% by weight of titanium, and about 0.01% to about 0.09% by weight of strontium are added to the molten metal of aluminum. The electric furnace may be heated at an average temperature more than about 800° C. (at most 850° C.) before tapping an ingot. Particular compositions of alloy additives provided to the electric furnaces may be same or different depending on modification of an ingot. The electric furnace is combined with a degassing and stirring machine at the degassing and stirring position. A degassing process removes hydrogen gas in the molten metal. The hydrogen gas may be generated from moisture, organic impurities or the like in a raw material. When the hydrogen gas is included in the molten metal, a pin hole may be generated in a die-casted product, or a strength of the die-casted product may be reduced. The hydrogen gas may be removed through fluxing, chlorine-refining, inline-refining or the like. Preferably, the hydrogen gas may be removed through Spinning Nozzle Inert Flotation or porous plugging at the degassing and stirring machine. Stirred molten metal is stabilized for about 20 to about 30 minutes at the stabilizing and ingot-tapping position and is maintained at a temperature appropriate for die-casting.

A ladle machine ladles the molten metal in the electric furnace at the stabilizing and ingot-tapping position, for example, by using a ladle of 5 kg, and pours the molten metal into an ingot casting mold of a transferring apparatus. The ladle machine pushes aside an oxide covering a surface of the molten metal in the electric furnace and ladles exposed molten metal in the ladle. The molten metal in the ladle is provided to the ingot casting mold through a delivery tube having a hopper shape.

The transferring apparatus includes a plurality of ingot casting molds mounted on a caterpillar and moves the ingot casting molds with a predetermined speed according to operation of a transferring motor. A transferring distance is enough long such that an aluminum alloy ingot can be natural-cooled and solidified in the course of the transferring process. At the end of transferring apparatus, an aluminum alloy ingot having a rectangular shape and about 5 kg may be obtained. The aluminum alloy ingot may be manufacture by an apparatus for manufacturing an aluminum alloy ingot, disclosed in Korean Patent Application No. 2013-0003183, applied by the same Applicant as the present invention.

Dye-Casting

Al aluminum alloy ingot is changed to molten aluminum alloy in a dye-casting melting furnace.

The aluminum alloy for die-casting according to an exemplary embodiment of the present invention does not generate hot tear in a die-casting process, and has a superior fillability. Furthermore, the aluminum alloy does not cause seizure to a mold, and has a superior die-castability. The seizure may be defined as a phenomenon that molten metal is welded on a surface of a mold thereby causing underfill or roughness after a casting process. Die-casting may be defined as manufacturing a casted product by injecting a molten metal into a mold. For example, the aluminum alloy for die-casting according to an exemplary embodiment of the present invention may be used for a high-speed high-pressure die-casing process or a vacuum die-casting process, but are not limited thereto.

A temperature of the molten aluminum alloy in a die-casting process may be about 700° C. to about 800° C., and preferably about 760° C. to about 790° C. A mold that may be used for the die-casting process is not specifically limited, and a conventional known mold may be used. Furthermore, since the aluminum alloy for die-casting according to an exemplary embodiment of the present invention has a superior die-castability, a shape of a mold is not specifically limited, and even a mold having a complicated shape may be used. A temperature of a die may be maintained in a range of about 200° C. to about 250° C. to reduce over-cooling when the aluminum alloy is solidified.

A die-casted product manufactured according to the above may have a high hardness. Thus, an anodized product obtained by anodizing a surface of the die-casted product may have a high hardness. Thus, the anodized product may be used for assembling process such as a nut process.

Test samples were prepared according to the following Table 1 in order to compare surfaces of die-cased products depending on a composition ratio of elements.

| | | | | | | impu- | Additives/ |
|---|---|---|---|---|---|---|---|
| | Mn | Zn | Zr | Ti | Sr | rities | Al (weight) |
| Example 1 | 2.7 | 1.4 | 0.45 | 0.06 | 0.09 | 0.2 | 4.9/95.1 |
| Example 2 | 3.0 | 0.7 | 0.45 | 0.05 | 0.01 | 0.2 | 4.41/95.59 |
| Comparative | 4.1 | — | 0.7 | 0.07 | 0.03 | 0.2 | 5.1/94.9 |
| Example 1 | | | | | | | |

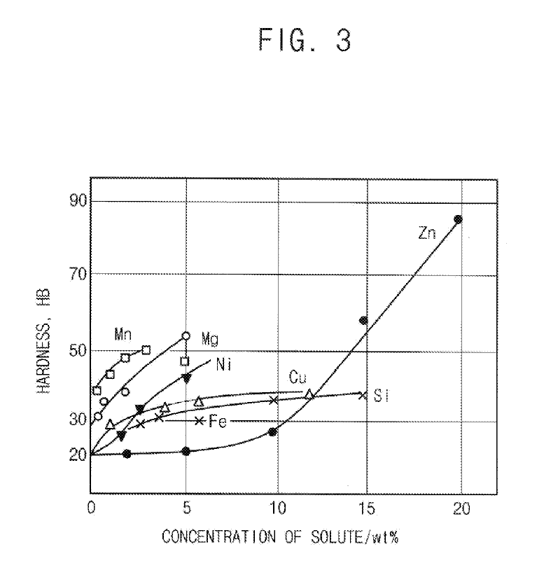

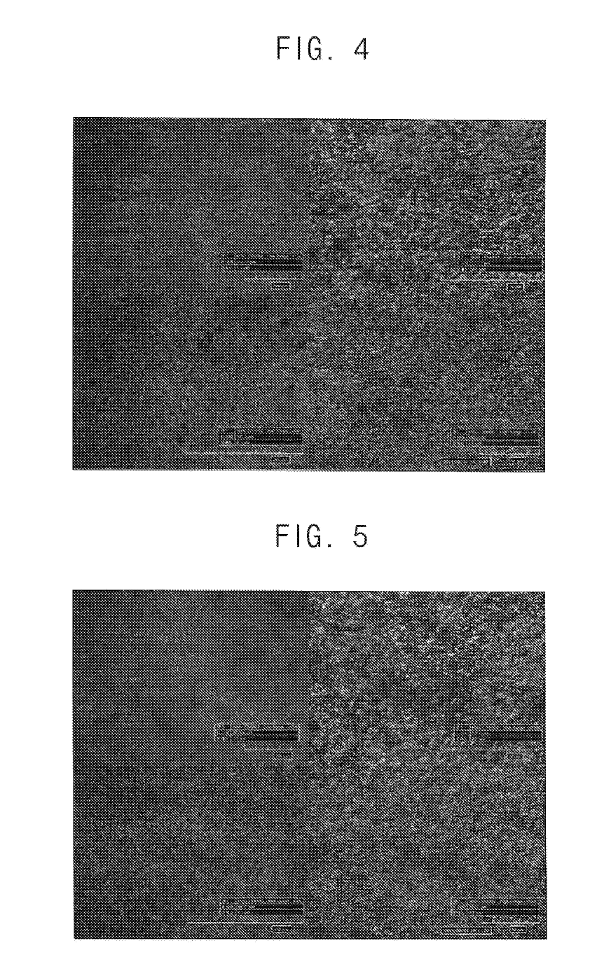

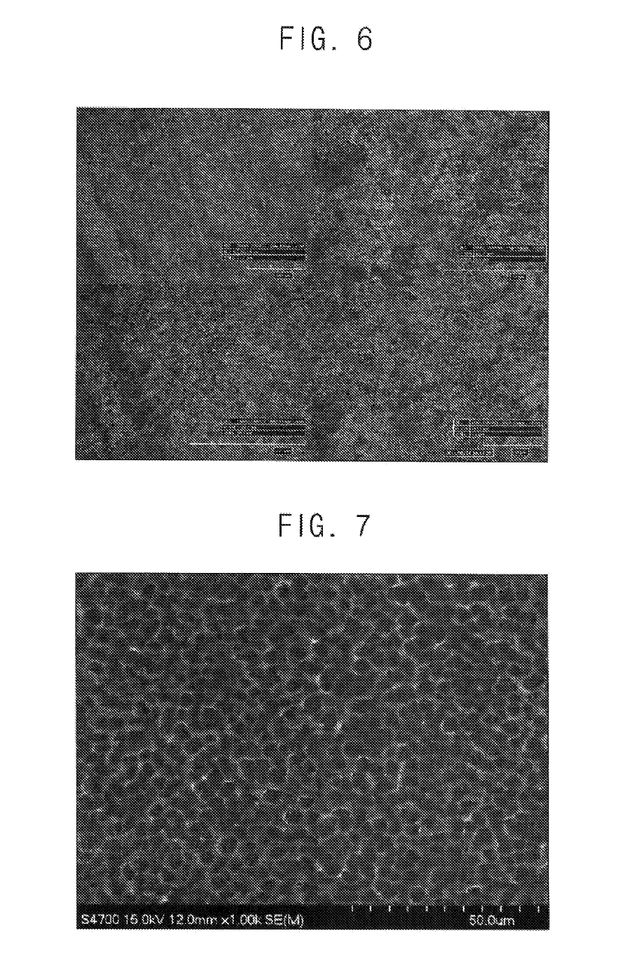

FIG. 4 is an optical microscopic picture, which shows a surface of the die-casted product of Example 1. FIG. 5 is an optical microscopic picture, which shows a surface of the die-casted product of Example 2. FIG. 6 is an optical microscopic picture, which shows a surface of the die-casted product of Comparative Example 1.

FIGS. 4 to 6 show pictures magnified by 150, 250, 1,500 and 2,500 in a clock-wise rotation, respectively. The die-casted products were etched to remove impurities before taking the pictures.

Referring to FIGS. 4 to 6, the die-casted products according to Examples 1 and 2 have uniform surfaces with compared to the die-casted product according to Comparative Example 1. Thus, it can be noted that the die-casted product according to Comparative Example 1 not including zinc has a deteriorated surface reflectivity with compared to the die-casted products according to Examples 1 and 2 including zinc.

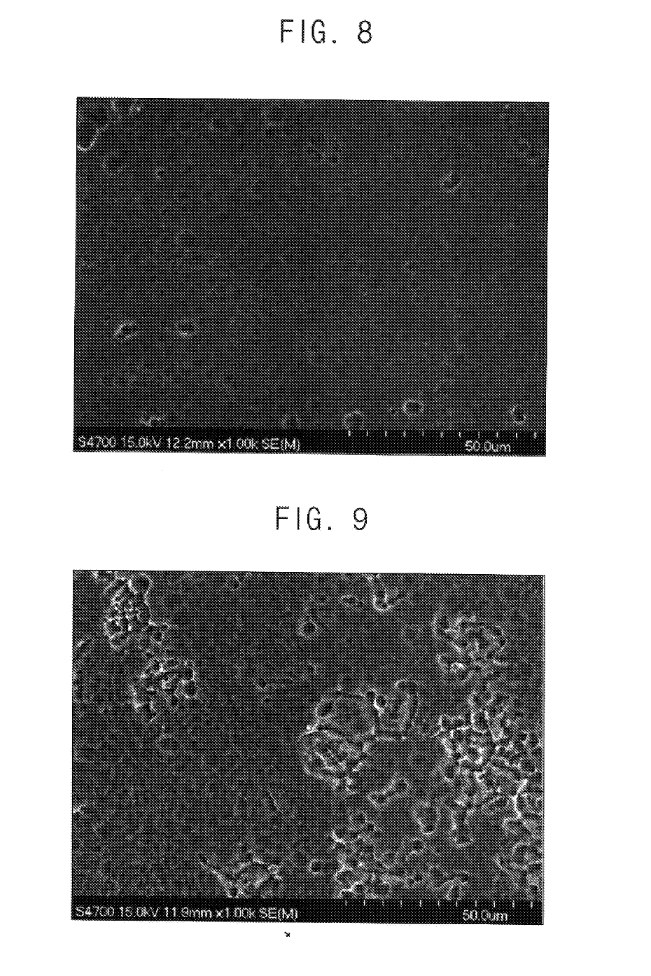

FIG. 7 is a scanning electron microscopic (SEM) picture, which shows a surface of the die-casted product of Example 1. FIG. 8 is an SEM picture, which shows a surface of the die-casted product of Example 2. FIG. 9 is an SEM picture, which shows a surface of the die-casted product of Comparative Example 1.

FIGS. 7 to 9 show pictures magnified by 1,000, respectively. The die-casted products were etched to remove impurities before taking the pictures.

Referring to FIGS. 7 to 9, uniformly formed alpha aluminum phase grains, which are dark portions, having a uniform size are observed in the die-casted product of Example 1. A bright line along an interface between the alpha aluminum phase grains is a eutectic structure. Alpha aluminum phase grains having reduced and irregular sizes are observed in the die-casted product of Example 2. A size of a eutectic structure is partially increased with compared to Example 1. Alpha aluminum phase grains that have irregular sizes and are dispersed irregularly in a eutectic structure are observed in the die-casted product of Comparative Example 1. Therefore, it can be noted that alpha aluminum phase grains are irregularly formed in the die-casted product of Comparative Example 1 having relatively more manganese without zinc and that alpha aluminum phase grains are increased and are uniformly formed with less manganese and more zinc.

In an exemplary embodiment of the present invention, an amount of aluminum may be preferably equal to or more than about 94% by weight to prevent seizure and to maintain a liquidity.

A rough segregation or a defect was not observed at a surface of the die-casted products of Examples 1 and 2. Furthermore, seizure was not observed at a surface of a die.

Anodizing

A die-casted product may be anodized after a conventional cleaning process, a conventional surface-treating process and the like.

For anodizing the die-casted product, the die-casted product may be dipped in a water solution including oxalic acid, boric acid, sulfuric acid, chromic acid or the like, and may be provided with a static electricity. Accordingly, a hard porous oxide layer is formed on a surface of the die-casted product. Thus, the die-casted product may be protected by the porous oxide layer.

A current density, a process temperature and a process time are not specifically limited, and may be varied appropriately depending on a side, a shape or a purposed of the die-casted product. Generally, the current density may be about 0.1 A/dm² to about 2 A/dm². The process temperature may be about 10° C. to about 70° C. The process time may be several to tens of minutes.

Furthermore, before anodizing the die-casted product, a surface of the die-casted product may be buffing-polished or chemically polished through a phosphoric composition to improve effects of an anodizing process.

A thin oxide layer of about 5 μm to about 20 μm may be formed on the die-casted product through the anodizing process. The oxide layer has a double-layered structure including a hard porous layer having a plurality of pores, which have a diameter of several to hundreds nm and are upwardly opened, and having a thickness of several μm, and a dense layer from a bottom of the pores to an interface with aluminum alloy. The anodized oxide layer has a great transmittance and maintains a metallic appearance after dyed. Thus, the die-casted product may have a high fanciness.

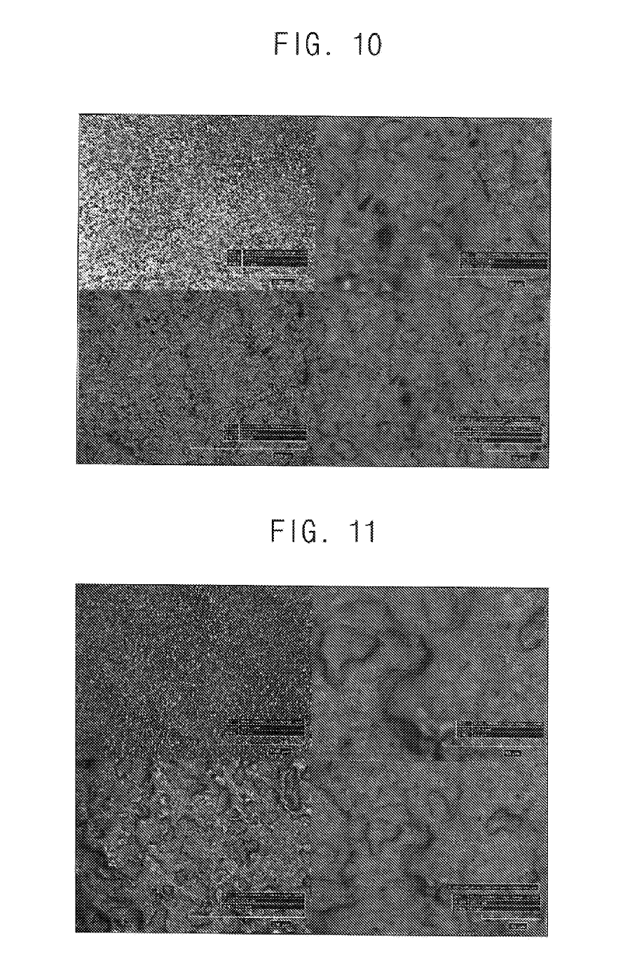

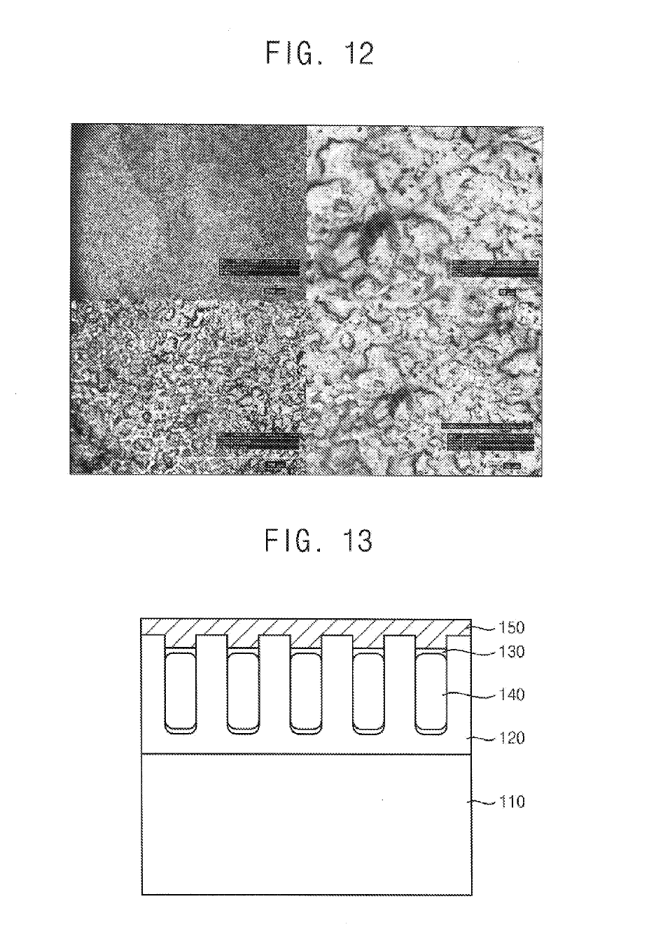

FIG. 10 is an optical microscopic picture, which shows a surface of the die-casted product of Example 1 after anodizing the die-casted product. FIG. 11 is an optical microscopic picture, which shows a surface of the die-casted product of Example 2 after anodizing the die-casted product. FIG. 12 is an optical microscopic picture, which shows a surface of the die-casted product of Comparative Example 1 after anodizing the die-casted product.

Referring to FIGS. 10 to 12, the die-casted products of Examples 1 and 2 had a uniform surface after anodized. However, the die-casted product of Comparative Example 1 had a relatively irregular surface after anodized.

Dyeing and Sealing

The die-casted product after anodized is dyed through a dyeing process providing dye into fine pores at a surface of the die-casted product.

For example, a dye or a metal salt adheres to fine pores of a surface oxide layer. A coloring agent is provided into the fine pores. Entrances of the fine pores are covered through a sealing process. Examples of dyeing methods may include an alumite method, in which a dye is adhered to an oxide layer, an electrolytic coloring method, in which a metal salt is adhered, and the like, however, are not specifically limited thereto. For example, when a dye is used, about 5 g to about 7 g of dye powder is added to about 11 of water, and a dyeing process is performed at about 60° C. to about 65° C. for about 10 to about 15 minutes.

A sealing process is performed after the dyeing process. Since the anodized oxide layer is porous and has a high absorption, the anodized oxide layer may be easily contaminated and may be unstable. Thus, the sealing process that blocks pores to reduce absorption is required. The sealing process is not specifically limited, and may be varied appropriately depending on a side, a shape or a purposed of the die-casted product. For example, a metal salt sealing method using a metal salt such as nickel acetate, cobalt acetate, borate or the like, a vapor sealing method using a pressed water vapor at more than about 100° C., or a low-temperature sealing method using fluoride may be used.

For example, the die-casted produced may be dipped in a nickel acetate solution (Ni(CH₃COO)₂4H₂O) to form a transparent sealing layer after a dye is filled in pores of the die-casted produced. For example, about 5 g to about 7 g of nickel acetate powder is added to about 11 of water, and the sealing process is performed at about 85° C. to about 90° C. for about 20 to about 25 minutes. The nickel acetate powder is solved and ionized in water and forms the sealing layer through a chemical reaction.

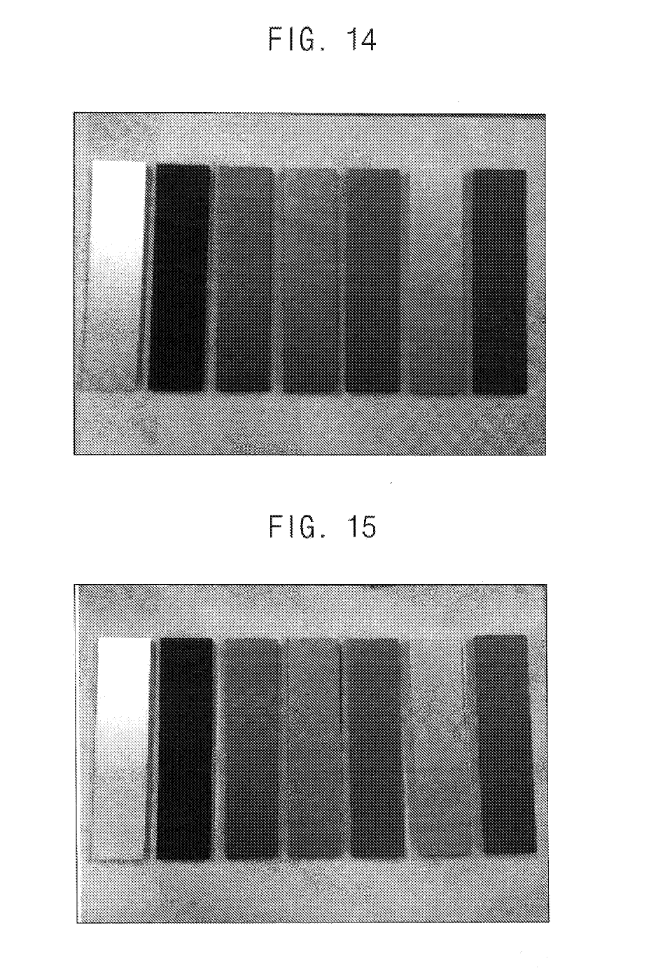

FIG. 13 is a cross-sectional view illustrating a case 100 of a portable electrical case manufacture by using aluminum alloy according to an exemplary embodiment of the present invention.

The case 100 includes an aluminum alloy core layer 110, an anodized layer 120, a fine pore 130, a dye layer 140 and a sealing layer 150. The anodized layer 120 and the sealing layer 150 are transparent to transmit light. The core layer 110 includes aluminum alloy including about 1.95% to about 4.10% by weight of manganese, about 0.1% to about 2.0% by weight of zinc, about 0.3% to about 0.8% by weight of zircon, about 0.03% to about 0.09% by weight of titanium, about 0.01% to about 0.09% by weight of strontium, and a remainder of aluminum. The anodized layer 120 includes the fine pores 130 having a depth. The dye layer 140 is disposed in and combined with the fine pores. The sealing layer 150 covers entrances of the fine pores.

A tensile strength of the case may be about 180 MPa to about 230 MPa.

Surface glossiness of samples manufactured according to the following was experimentally evaluated.

Glossiness may be defined as a regular reflection amount of an incident light on a surface of an object. In JIS standard (JIS Z8741), 100% of glossiness may be defined as 10% of a reflectivity at a surface of a glass substrate having 1.567 of refractivity with 60 degrees of an incident angle, or as 5% of reflectivity with 20 degrees of an incident angle.

A dye-casted product manufactured by an exemplary embodiment of the present invention has about 150% to 300% of glossiness with 60 degrees of an incident angle. The glossiness may be measured by a conventional gloss meter. A color tone and a smear may be observed by human eyes.

The following samples for cases were prepared through chemical polishing for 15 seconds and anodizing using sulfuric acid for 15 to 50 minutes at 12V to 15V to form an anodized layer of 6 to 20 μm. The gloss meter was PG-1M manufactured by NIPPON DENSHOKU.

TABLE 2
Comparison of glossiness

| | | | | | | impu- | Additives/ | gloss- |
|---|---|---|---|---|---|---|---|---|
| | Mn | Zn | Zr | Ti | Sr | rities | Al (weight) | iness |
| Example 1 | 2.7 | 1.4 | 0.45 | 0.06 | 0.09 | 0.2 | 4.9/95.1 | 292.3 |
| Example 2 | 3.0 | 0.7 | 0.45 | 0.05 | 0.01 | 0.2 | 4.41/95.59 | 179.4 |
| Comparative | 4.1 | — | 0.7 | 0.07 | 0.03 | 0.2 | 5.1/94.9 | 143.7 |
| Example 1 | | | | | | | | |

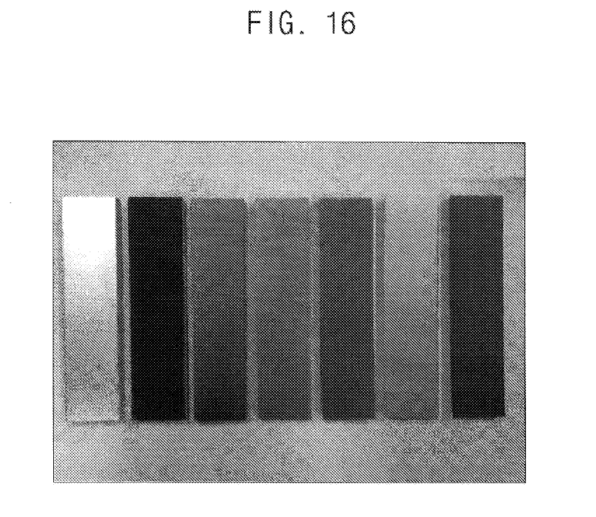

FIG. 14 is a picture showing the sample cases manufactured by using the aluminum alloy of Example 1. FIG. 15 is a picture showing the sample cases manufactured by using the aluminum alloy of Example 2. FIG. 16 is a picture showing the sample cases manufactured by using the aluminum alloy of Comparative Example 1.

The sample cases have a same size and were dyed with 7 different colors including white, black, dark gray, bright gray, red, gold and purple.

Referring to FIGS. 14 to 16, the sample cases manufactured by using the aluminum alloy of Example 1 have the brightest color tone in contrast that the sample cases manufactured by using the aluminum alloy of Comparative Example 1 have relatively dark color tone.

TABLE 3
Comparison of properties

| | Mn | Zn | Zr | Ti | Sr | Imp. | A/A | GL | TS | YS | HD | EL |
|---|---|---|---|---|---|---|---|---|---|---|---|---|
| E1 | 2.7 | 1.4 | 0.45 | 0.06 | 0.09 | 0.2 | 4.9/95.1 | 292.3 | 190 | 115 | 79 | 16 |
| E2 | 3.0 | 0.7 | 0.45 | 0.05 | 0.01 | 0.2 | 4.41/95.59 | 179.4 | 210 | 135 | 82 | 18 |
| E3 | 3.5 | 0.7 | 0.8 | 0.05 | 0.07 | 0.2 | 5.32/94.68 | 160 | 224 | 150 | 86 | 19 |
| CE1 | 4.1 | — | 0.7 | 0.07 | 0.03 | 0.2 | 5.1/94.9 | 143.7 | 230 | 150 | 86 | 10 |
| CE2 | 4.5 | 1.4 | 0.45 | 0.05 | 0.01 | 0.2 | 6.61/93.39 | 110 | 213 | 110 | 79 | 19 |
| CE3 | 2.0 | — | 0.45 | 0.06 | 0.08 | 0.2 | 2.79/97.21 | 264 | 169 | 95 | 67 | 17 |
| CE4 | 2.0 | 2.0 | 0.45 | 0.07 | 0.08 | 0.2 | 4.8/95.2 | 295 | 168 | 100 | 70 | 18 |
| CE5 | 3.5 | 1.4 | 0.2 | 0.06 | 0.04 | 0.2 | 5.4/94.6 | 170 | 151 | 102 | 62 | 27 |

Further sample cases were prepared by using aluminum alloys of Example 3 and Comparative Examples 2 to 5. Furthermore, tensile strength (TS), yield strength (YS), hardness (HD) and elongation (EL) for the samples cases manufactured by using the aluminum alloys of Examples 1 to 3 and Comparative Examples 1 to 5 were measured and represented in Table 3. The hardness is represented by a surface hardness (HV) according to Vicker's hardness test of JIS Z2244. The hardness may be preferably equal to or more than 75HV, and may be measured by a conventional hardness tester. In Table 3, E1, E2 and E3 represents Example 1, Example 2 and Example 3, respectively, and CE1, CE2, CE3, CE4 and CE5 represents Comparative Example 1, Comparative Example 2, Comparative Example 3, Comparative Example 4 and Comparative Example 5, respectively.

Referring to Table 3, when an amount of manganese increases as known by Examples 1 to 3, alpha aluminum phase grains are reduced and irregularly formed so that mechanical properties such as strength and hardness are increased. However, glossiness is reduced to represent a dark color tone.

Furthermore, when an amount of zinc increases as known by Examples 1 to 3, alpha aluminum phase grains are increased and uniformly formed so that mechanical properties such as strength and hardness are reduced. However, glossiness is increased to represent a bright color tone.

Referring to Examples 1 to 3, when an amount of manganese increases, mechanical properties are increased. However, glossiness is reduced.

Referring to Comparative Example 1, it can be noted that maximizing manganese without zinc can achieve superior mechanical properties. However, the desired glossiness cannot be obtained.

Referring to Comparative Example 2, it can be noted that excess of manganese forms rough intermetallic compound to cause blackening thereby reducing glossiness.

Referring to Comparative Example 3, it can be noted that minimizing manganese without zinc can achieve superior glossiness. However, the tensile strength is too low to be used for a case of an electrical apparatus.

Referring to Comparative Example 4, it can be noted that minimizing manganese with increased zinc can improve glossiness. However, tensile strength is still too low.

Referring to Comparative Example 5, it can be noted that minimizing zircon reduces the tensile strength even if manganese is added.

Therefore, proper ratios of manganese, zinc and zircon need to be maintained so that aluminum alloy may provided mechanical properties required for a case of an electrical apparatus, glossiness, die-castability and surface color uniformity for anodizing.

The foregoing is illustrative of the present inventive concept and is not to be construed as limiting thereof. Although a few example embodiments of the present inventive concept have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of the present inventive concept and is not to be construed as limited to the specific example embodiments disclosed, and that modifications to the disclosed example embodiments, as well as other example embodiments, are intended to be included within the scope of the appended claims. The present inventive concept is defined by the following claims, with equivalents of the claims to be included therein.

What is claimed is:

1. An aluminum alloy for die-casting, the aluminum alloy comprising:
about 1.95% to about 4.10% by weight of manganese;
about 0.1% to about 2.0% by weight of zinc;
about 0.3% to about 0.8% by weight of zircon;
about 0.03% to about 0.09% by weight of titanium; and
a remainder of aluminum.

2. The aluminum alloy of claim 1, wherein the aluminum alloy comprises about 2.5% to about 3.5% by weight of manganese.

3. The aluminum alloy of claim 1, further comprising about 0.01% to about 0.09% by weight of strontium.

4. The aluminum alloy of claim 3, wherein an amount of aluminum is equal to or more than about 94% by weight.

5. A method for manufacturing a case of a portable electrical apparatus, the method comprising:
forming a molten aluminum alloy including about 1.95% to about 4.10% by weight of manganese, about 0.1% to about 2.0% by weight of zinc, about 0.3% to about 0.8% by weight of zircon, about 0.03% to about 0.09% by weight of titanium, about 0.01% to about 0.09% by weight of strontium, and a remainder of aluminum;
providing the molten aluminum alloy into a die;
separating an aluminum alloy die-casted product from the die;
anodizing a surface of the aluminum alloy die-casted product;
providing a dye into fine pores at a surface of the anodized aluminum alloy die-casted product; and
sealing the fine pores.

6. The method of claim 5, wherein the molten aluminum alloy comprises about 2.5% to about 3.5% by weight of manganese.

7. The method of claim 5, wherein a temperature of the molten aluminum alloy is about 700° C. to about 800° C.

8. The method of claim 7, wherein a temperature of the molten aluminum alloy is about 760° C. to about 790° C.

9. The method of claim 5, wherein a temperature of the die is about 200° C. to about 250° C.

10. A case of a portable electrical apparatus, the case comprising:
a core layer including aluminum alloy including about 1.95% to about 4.10% by weight of manganese, about 0.1% to about 2.0% by weight of zinc, about 0.3% to about 0.8% by weight of zircon, about 0.03% to about 0.09% by weight of titanium, about 0.01% to about 0.09% by weight of strontium, and a remainder of aluminum;
an anodized layer including a plurality of fine pores formed at a surface of the core layer and having a depth;
a dye layer disposed in and combined with the fine pores; and
a sealing layer covering entrances of the fine pores.

11. The case of claim 10, wherein the aluminum alloy comprises about 2.5% to about 3.5% by weight of manganese.

12. The case of claim 10, wherein a glossiness of the case is about 150% to 300% of glossiness with 60 degrees of an incident angle, when 100% of glossiness may be defined as 10% of reflectivity with 60 degrees of an incident angle.

13. The case of claim 10, wherein a tensile strength of the case is about 180 MPa to about 230 MPa.
